(19) United States
(12) Patent Application Publication
(10) Pub. No.: US 2005/0274770 A1
(43) Pub. Date: Dec. 15, 2005

(54) Method for the precise and reliable placement of solid metallic and non-metallic particles

(76) Inventor: Marvin Allen Henderson SR., Yale, MI (US)

Correspondence Address: Marvin Henderson, 13248 Speaker Road, Yale, MI, 48097, US

(21) Appl. No.: 10/862,154

(22) Filed: Jun. 7, 2004

(51) Int. Cl. B23K 5/00; B23K 1/08; B23K 20/14

(52) U.S. Cl. 228/41; 228/39

(57) ABSTRACT

Vibrational energy is used to fluidize a bed of particulate material over the top surface of a tooling plate with particle alignment hole passing from its top to bottom side. The particle alignment holes are slightly smaller than the particles in the particulate bed. The vibrational energy's frequency, amplitude, orientation, and phase relationships are applied in such a manner as to generate controlled motion within the fluidized particle bed. This motion is used to move the individual particles within the fluidized particle bed to positions from which they can be pulled, by gravity, into the tooling plate's particle alignment holes. Once in the alignment holes, the individual particles is acted upon by gravity and pulled down onto a contact surface that is coated with a tacky substance. The tacky substance causes the particle to adhere to the contact surface. While this invention can be applied to the placement of solder balls in ball grid array, its application and scope are not limited to ball grid array.

### BACKGROUND OF INVENTION

Two methods are used in the placement of solder balls in BGA and micro BGA technologies. The first utilizes a tooling plate containing an array of solder ball alignment holes. These are precisely placed to match metallized contact sites on the object to be populated. The solder balls are to be placed on these metallized contact sites. The solder balls pass through the tooling plate's solder ball alignment holes during the placement process. The solder ball alignment holes align the solder balls with the metallized contacts. The solder ball alignment holes are significantly larger than the solder balls. This facilitates the entrance of the solder balls into the holes. This also adversely affects the placement precision of the system, limiting the array's density. The second method utilizes a pick up and transfer head. This head picks up solder balls from an agitated or gas fluidized reservoir and transfers them directly to the metallized contacts on the object to be populated. Systems utilizing this methodology rely upon a complex pick up head that utilizes vacuum to pull individual solder balls into catchments in the head's lower surface. These are sometimes located at the ends of hollow tubes. Once the tooling head has been located over the contact sites, the vacuum is released. This results in the solder balls being released directly onto the contact sites. The pick up heads utilized by this methodology tend to be complex and do not always fully populate when submersed into the solder ball reservoir. These failures result in a significant number of unpopulated metallic contacts

Both of the methods list above require that a tacky material be present on the contact sites of the object to be populated. The purpose of this tacky substance is to cause the solder balls to adhere to the contact site. In the cases of BGA and mBGA, flux is utilized to this purpose. It adheres to both the metallized contacts and the solder. In addition, the flux plays an active role in the soldering process that occurs subsequent to solder ball placement. The flux can be applied to the contact sites in a number of ways. These methods include, but are not limited to silk screening, spraying, rolling, and flooding.

The primary difference in the methods utilizing tooling plates is the means by which the solder balls are fed into the tooling plate's particle (solder ball) alignment holes.

One method that has been utilized to place solder balls into the tooling plate's solder ball alignment holes has been to place them manually. This methodology is highly labor intensive, time consuming, and subject to human error.

Another method that has been utilized to place solder balls into the tooling plate's solder ball alignment holes is to cascade them across a tilted tooling plate. This methodology is highly dependent upon the size, mass, kinetic energy, and shape of the solder balls; particle to particle interaction within the solder ball bed; the coefficient of friction between the solder balls and the tooling plate's surface; the tooling plate's angle of tilt; and the size of the tooling plate's solder ball alignment holes. Experience has shown this method's ability to reliably populate all of a tooling plate solder ball alignment holes to be less than desirable. The factors listed above necessitate the use of a tooling plate solder ball alignment hole that is significantly larger than the solder ball diameter. This adversely affects the solder ball placement precision. It also limits the array density. Those machines that utilize this method tend to be mechanically complex systems. This generates reliability concerns.

Another method that has been utilized to place solder balls into the tooling plate's solder ball alignment holes is to slide an open bottomed solder ball reservoir across the surface of the tooling plate allowing gravity to cause individual solder balls to fall into individual solder ball alignment holes. Friction between the individual solder balls, between the solder balls and the reservoir's sides, and between the solder balls and the tooling plates surface produces solder ball bridging within the sliding reservoir. This bridging prevents the uniform flow of the solder balls and results in a significant number of unpopulated tooling plate solder ball alignment holes and, as the result, unpopulated contact sites. Like the preceding method, this methods reliability is less than desirable and requires mechanically complex systems to implement.

Failure to reliably populate all of the contact sites on the target devise is a significant shortcoming of the particle (solder ball) placement methods being utilized today. Failure to precisely place particles is another significant shortcoming. These shortcomings limit their usefulness. They limit array size in that they limit the number of particles used within an individual array and limit the minimum spacing between placed particles within an array necessitating the use of large array footprints. Taken together, these shortcoming limit the degree of miniaturization that can be achieved.

In at least one method, currently in use, the solder balls on the tooling plate are agitated. The theory in doing so is that this agitation aids one of the filling methods described above in the filling of the tooling plate solder ball alignment holes. Experience has shown that agitation results in as many, if not more, solder balls being expelled from tooling plate alignment holes as being induced to enter. Agitation also result in a significant transfer of flux to the alignment hole wall. This transferred flux traps subsequent solder balls, clogging the hole.

Agitation results in random uncontrolled motion that cannot be construed to be the fluid motion produced by the type of vibratory fluidization utilized in this invention. Vibrational fluidization does not impart sufficient kinetic energy to the solder balls to cause them to be expelled from the tooling holes. It also does not impart sufficient kinetic energy to cause the solder balls to break free from the fluxed contact sites. Therefore, it does not transfer flux to the tooling hole walls.

Fluidization is utilized by a number of the methods covered above. Without exception, that fluidization is limited to the solder ball reservoir and is achieved by either the flow of a gas through a particle reservoir or by vibration of the reservoir. In each case, this is performed to facilitate the delivery of particles to the tooling plate. This fluidization plays no role in the population of the tooling plate's solder ball alignment holes. This invention applies to the facilitation of the population of the tooling plate's particle alignment holes through the fluidization of the particulate matter while it is on the tooling plate.

### BRIEF DESCRIPTION OF DRAWINGS

FIG. 1: Number—1—Tooling plate particle alignment holes. The figure shows the arrays for two devices. Number 2 shows the individual particle alignment holes. Number 3 shows the smaller alignment holes through which alignment pins will pass prior to particle placement. The alignment pins guarantee correct registration between the tooling plate alignment holes and the device being populated. Other means of registration may be employed. Number 4 shows the metallized contacts utilized in ball grid array. Depending upon the nature of the contact, the particle being placed upon it, and the nature of the bond being produced, the contact surface may or may not be metallized. Number 5 shows the device being populated.

FIG. 2: Number 1 shows the tooling plate. Number 2 shows particles inside the tooling plate particle alignment holes. Number 3 shows the tacky substance utilized to attached the particle to the contact. In the case of ball grid array, flux is used for this purpose. In other applications other substances may be used. For example, an adhesive. Number 4 shows the contact pad on the device. In the case of ball grid array this is copper and may be coated with gold or other metals for corrosion and or mechanical protection. Number 5 shows the substrate that supports both the contacts and the device to be attached. In the case of ball grid array, this may be, but not be limited to, a printed circuit board, a ceramic substrate, or a connector. Number 6 is the device or other item being attached.

FIG. 3: Number 1 represents one of the directions to which vibrational energy may be applied to the tooling plate, the tooling plate fixture, or tooling plate housing. This is referred to as the longitudinal horizontal axis. Number 2 represents another of the directions to which vibrational energy may be applied to the tooling plate, the tooling plate fixture, or tooling plate housing. This is referred to as the transverse horizontal axis. Number 3 represents another of the directions to which vibration may be applied to the tooling plate or the tooling plate fixture or the tooling plate housing. This is referred to as the vertical axis. Vibrational energy may be applied in any single or combination of these direction to obtain the desired particle movement. Vibrational energy may also be applied to the tooling plate, the tooling plate fixture, or the tooling plate housing or any combination of these to obtain the desired particle movement.

FIG. 4: Number 1 shows the tooling plate. Number 2 shows a particle inside one of the tooling plate's alignment holes. Number 3 shows the particulate bed. Number for shows the wave motion within the particulate bed generated by the vibrational energy. Number 5 shows individual particles within the particulate bed.

FIG. 5: Figure represents the essential components of the invention. Number 1 is the particle placement chamber. Number 2 is the tooling plate and tooling plate frame. Number 3 are the alignment pins that align the contact sites on the object being populated with the tooling plate's particle alignment holes. Number 4 is the object being populated. Number 5 is the input gate. Number 6 is the exit gate. Number 7 is the reservoir storing the supply of particles. Number 8 is the pneumatic impellor that sends the excess particles back to Number 7. Number 9 is the excess loose particle capture reservoir. Number 10 is the pneumatic tube through which particles are returned to Number 7. Number 13 is the flexible tube through which particles are fed to the input gate. Number 14 is the flexible tube through which excess loose particles are fed to the capture reservoir, Number 9. The 0 degree value represents the relationship between tooling plate's surface and an imaginary horizontal plane. Number 4, the object being populated, has not, in the figure, been lifted to the tooling plate and has not been latched to the tooling plate frame.

FIG. 6 shows the object being populated, Number 4, lifted to the tooling plate and latched to the tooling plate frame.

FIG. 7 shows the bed of particulate matter (solder balls), Number 11, on the tooling plate's surface after the input gate, Number 5, has been opened. Once the correct number (volume) of particulate matter has flown into the particle placement chamber, the input gate, Number 5, closes and the variable frequency and variable amplitude vibrators are activated fluidizing the particle bed. This continues until all of the tooling plate's particle alignment holes are filled.

FIG. 8 shows the particle placement chamber (Number 1) tooling plate and tooling plate frame (Number 2), and the object being populated in the tilted position. After the tooling plate's particle alignment holes are filled, the exit gate (Number 6) opens and the above named assembly is tilted to facilitate the flow of excess loose particles (solder balls) from the particle placement chamber (Number 1) through the exit gate (Number 6) into the Number 9, the excess loose particle capture reservoir. After all of the ball have flowed from the particle placement chamber (Number 1), the exit gate (Number 6) closes and the variable frequency variable amplitude vibrators are deactivated.

FIG. 9 shows the particle placement chamber (Number 1), tooling plate and tooling plate frame (Number 2), and the object being populated (Number 4) assembly returned to the horizontal position.

FIG. 10 shows the object being populated (Number 4) unlatched and lowered from the bottom of the tooling plate and shows the particles (solder balls) (Number 12) that were deposited during the operation.

### DETAILED DESCRIPTION

This invention may be utilized to precisely and reliably place both metallic and non-metallic particles of any shape. This description, but not this invention, will be limited, for simplicity of description, to one of its applications. That application being the placement of spherical metallic particles. Such spherical metallic particles, solder balls, are frequently used in the electronics industry to attach integrated circuits and other items to printed circuit boards, to ceramic substrates, and to electrical connectors. It may also be utilized in the formation of other connections and mountings. Two of the technologies that would utilize this invention are referred to as Ball Grid Array (BGA) and Micro Ball Grid Array (mBGA). Both involve the placement of small particles, solder balls, upon fluxed metallized contact points on printed circuit boards, integrated circuits, connectors, and other devices and structures. Subsequent to placement upon the fluxed metallized contact points, the solder balls are melted. The molten solder wets the metallized contact points and upon cooling solidifies. These solder bumps later provide the basis for attaching the object to a larger assembly.

By applying vibrational energy to a bed of particulate matter (i.e. solder balls), the particulate bed can be made to behave as a fluid. The frequency and amplitude of the vibrational energy needed to fluidize a particulate bed is dependent upon a number of factors including, but not limited to, the particulate matter's shape, size, and mass.

By controlling the frequency, the amplitude, the phase relationships, and the orientation of vibrational energy delivered to a particulate bed, it can be made to flow in a controlled, non-random manner. This is not the random motion associated with agitation. In addition to fluidization, vertical vibration, applied perpendicular to the plane of a thin particulate bed, can produce, depending upon the frequency and amplitude of the vibrational energy being applied, subharmonic patterns consisting of stripes, squares, hexagons, and localized structures. Horizontal vibration, applied in the plane of a thin particulate bed, can produce, depending upon the frequency and amplitude of the vibrational energy, motion within the particle bed. This motion can include wave action. By employing the above principles to fluidize the particulate bed and to generate controlled motion within it, the particulate matter within the particulate bed can be made to move back and forth in a controlled manner over a tooling plate's particle alignment holes. Each time an individual particle passes over a tooling plate alignment hole, there is a finite probability that it will be pulled, by gravity, into it.

Because the particulate matter is oscillating at sonic and higher frequencies, the number of times that each particle is presented, that is to say, comes into a position from which it can enter one of the tooling plate's particle alignment holes, is considerably increased. This significantly increases the probability that the particle will be pulled, by gravity, into one of the tooling plate's particulate alignment holes.

Because the vibrational energy needed to fluidize a particulate bed is less than that needed to agitate the particulate bed, fewer particles will be ejected from to tooling plate's alignment holes once they have entered. This increases the probability that the individual tooling plate alignment hole will be occupied. Those methods that utilize agitation frequently throw particles from alignment holes leaving unpopulated contact sites.

Because the particulate matter is presented to the tooling plate's ball alignment holes numerous times, the size of individual holes may be decreased, significantly increasing the precision of particle placement.

Because the particle alignment holes and their spacing can be made smaller, higher package densities can be realized.

Because a particulate bed requires less vibrational energy to fluidize than to agitate, fewer particles, solder balls, once they have been captured by the flux on the metallized contacts will break free. This minimizes the transfer of flux to the inside walls of the tooling plate's particle alignment holes thereby minimizing the probability that subsequent balls will adhere to the hole's sides clogging the hole.

Because particulate matter movement is achieved by means of fluid flow the placement mechanism requires significantly fewer moving parts than all preceding methods except that of hand placement. Manual placement however is prone to human error and is very time consuming.

Vibrational energy applied to a bed of particulate material, when the frequencies; amplitude; phase relationship; orientations, and durations are correct, will fluidize the bed. By controlling the frequency; amplitude; phase relationship; and orientation of the vibrational energy applied to a bed of particulate material this invention creates controlled motion within the bed of particles. This controlled motion is utilized to facilitate the placement of the fluidized particulate matter, solder balls, into precisely placed particle, solder ball, alignment holes in a tooling plate. Because the induced oscillation of the particulate matter, solder balls, occurs at the frequency of sound or higher, this invention significantly increases the probability of an individual particle, solder ball, moving into a position from which it can be pulled, by gravity, into one of the tooling plate's particle, solder ball, alignment holes over the probabilities generated by other particle placement systems. This results in a higher probability of fully populating all of the contact sites of a device. This invention is an improvement over current methods which leave a significant number of contact sites unpopulated which render a device unusable. This invention enables smaller tooling plate particle, solder ball, alignment holes to be used. This allows higher contact site densities to be utilized, resulting in an overall decrease in final package size. This invention's use of smaller tooling plate particle, solder ball, alignment holes, with a given solder ball size, results in more precise placement. When applied to BGA and mBGA, this invention will increase the precision of solder ball placement, allow small device foot prints to be realized, and will increase the placement process yield over existing methodologies.

The process by which this occurs is as follows:

The device that is to be populated with particulate material, solder balls, is placed within the tacky material applicator. Inside the tacky material applicator, the contact sites on the object to be populated receives a coating of a tacky material. Flux is used as the tacky material in most BGA and mBGA applications. Application may be achieved by screening, spraying, rolling, or flooding the contacts or by any other suitable method.

The device that is to be populated is transferred to the underside of the tooling plate, which is the bottom of the placement chamber. It is aligned with (i.e. through the use of alignment pins or other suitable means) and clamped to the bottom of the tooling plate/tooling plate frame assembly. This places the contact sites in alignment with the tooling plate's particle alignment holes. FIG. 6 shows all of the essential components of this invention except the variable frequency variable amplitude vibrators.

The top of the tooling plate forms the bottom of the particle placement chamber. The particulate matter (solder balls) are fed to the placement chamber's input gate which is located in the side of the placement chamber. The input gate is located in the side of the placement chamber. The input gate is opened to allow the particulate matter (solder balls) to flow from a reservoir into the placement chamber flooding the surface of the tooling plate. After the prescribed number or volume of particles (solder balls) flows into the placement chamber, the input side gate is closed. FIG. 7.

Variable frequency variable amplitude vibrational energy is applied to the tooling plate, the tooling plate frame, or the placement chamber individually or any combination of the three. The frequency, amplitude, orientation, and phase relationship of the vibrational energy is adjusted to fluidize the particle bed inside the placement chamber and to cause it to move in the manner desired. Under the influence of the vibrational energy, the particles, solder balls, within the particle bed will move to the mouths of the tooling plates particle, solder ball, alignment holes and will be pulled, by gravity, into the alignment holes.

The particle bed is kept in a fluidized state for a sufficiently length of time to allow the full population of the tooling plate's particulate alignment holes.

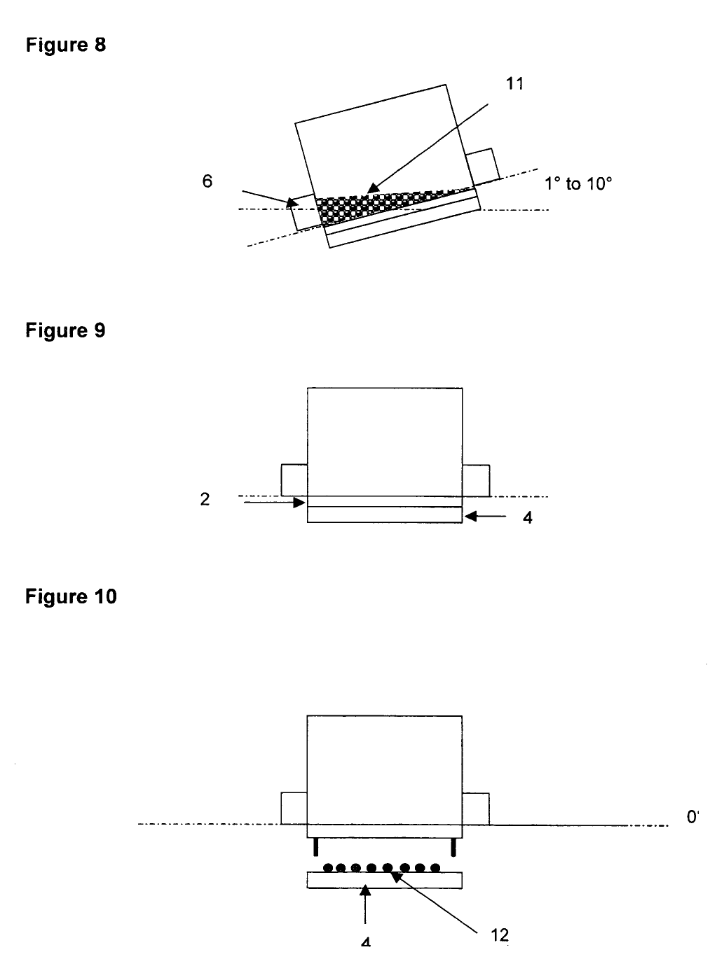

The excess particulate matter, solder balls, is removed from the tooling plate's upper surface. This is achieved by tipping the tooling plate towards the output gate (located on the opposite side of the placement chamber from the input gate) while the particulate bed is still fluidized. While this is occurring, or slightly before, the output gate is opened. This allows the excess particulate matter, solder balls, to leave the placement chamber and be transferred to a capture reservoir and ultimately back to the initial reservoir to be reused. FIG. 8.

The vibrational energy is removed from the system. FIG. 9.

The device being populated is unclamped and lowered from the tooling plate.

The populated device is moved to the next manufacturing operation. FIG. 10.

Figures:

All Figures are contained on the accompanying CD's (2) named Mhenderson Patent Copies 1 and 2. Both CD's have identical contents.

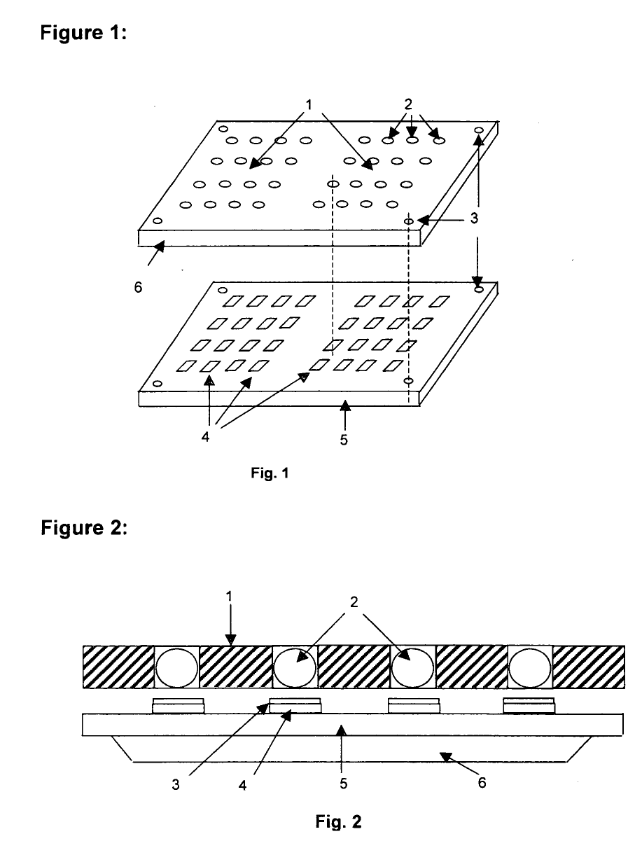

Insert “FIGS. 1 and 2 Tiff 4.tif”

Located on the accompanying CD: Disk name: Mhenderson Patent Copies 1 and 2:

| File Name: | Size: | Creation Date: | Copied to CD on: |
|---|---|---|---|
| FIG. 1 and 2 Tiff 4.tif. | 464 KB | May 29, 2004 | Oct. 10, 2004. |

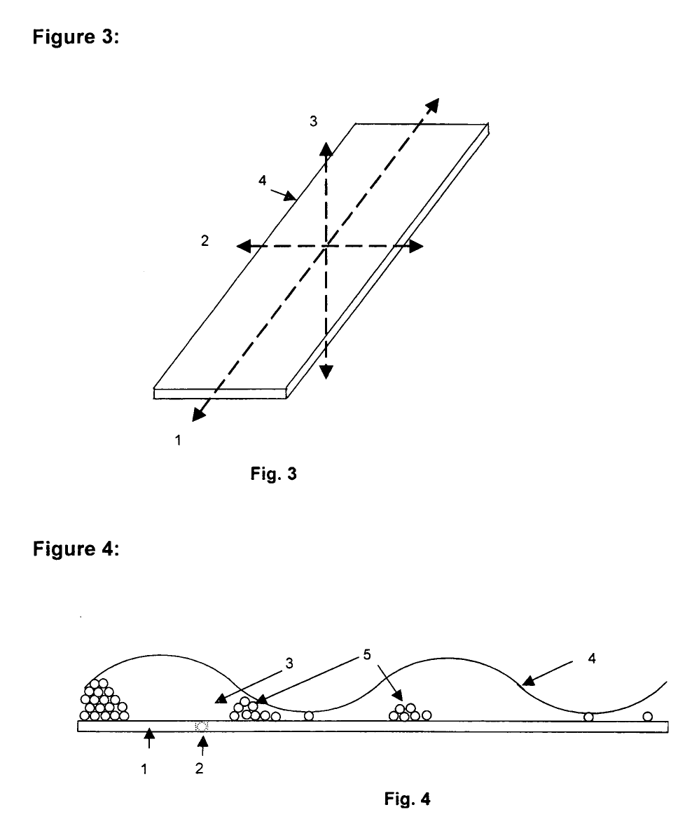

Insert “FIGS. 3 and 4 Tiff 4.tif”

Located on the accompanying CD: Disk name: Mhenderson Patent Copies 1 or 2:

| File Name: | Size: | Creation Date: | Copied to CD on: |
|---|---|---|---|
| FIG. 3 and 4 Tiff 4.tif | 486 KB | May 29, 2004 | Oct. 10, 2004 |

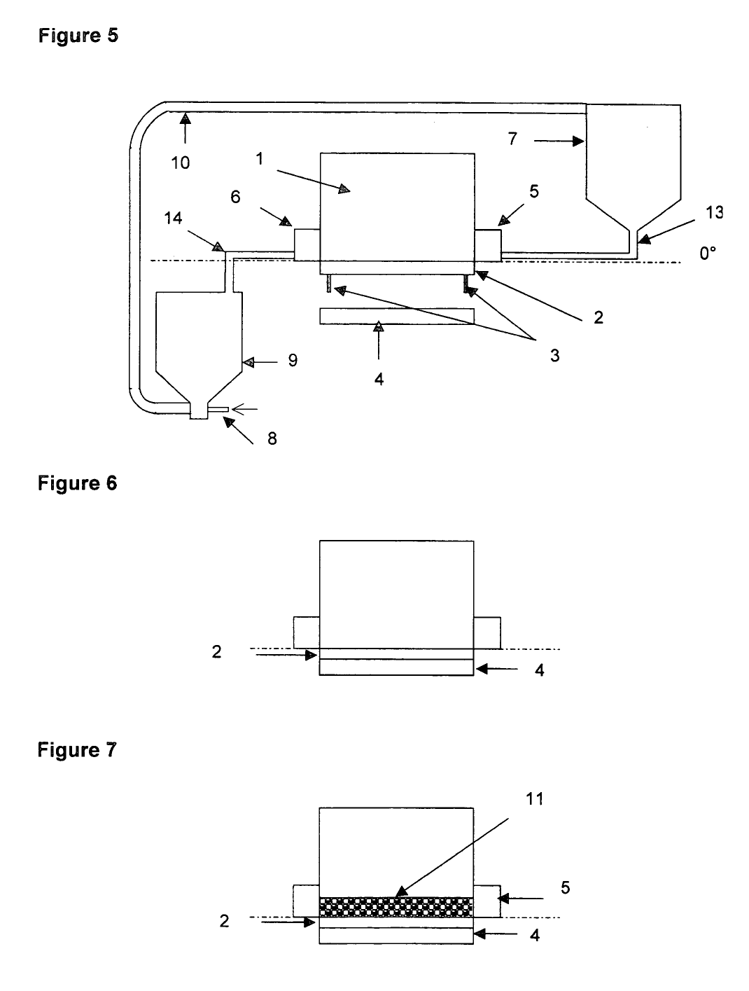

Insert “FIGS. 5 and 6 and 7 Tiff 4.tif”

Located on the accompanying CD: Disk name: Mhenderson Patent Copies 1 or 2:

| File Name: | Size: | Creation Date: | Copied to CD on: |
|---|---|---|---|
| FIG. 5 and 6 and 7 Tiff | 617 KB | May 29, 2004 | Oct. 10, 2004. |
| 4.tif. | | | |

Insert “FIGS. 8 and 9 and 10 Tiff 4.tif”

Located on the accompanying CD: Disk name: Mhenderson Patent Copy 1 or 2:

| File Name: | Size: | Creation Date: | Copied to CD on: |
|---|---|---|---|
| FIG. 8 and 9 and 10 Tiff | 601 KB | May 29, 2004 | Oct. 10, 2004. |
| 4.tif. | | | |

Directories of CD's Mhenderson Patent Copies 1 and 2:

| File Name: | Size: | Created: | Copied to CD: | Format: |
|---|---|---|---|---|
| FIG. 1 and 2 | 464 KB | May 29, 2004 | Oct. 11, 2004 | Tif |
| Tiff 4.tif. | | | | |
| FIG. 3 and 4 | 486 KB | May 29, 2004 | Oct. 11, 2004 | Tif |
| Tiff 4.tif | | | | |
| FIG. 5 and 6 and 7 | 617 KB | May 29, 2004 | Oct. 11, 2004 | Tif |
| Tiff 4.tif. | | | | |
| FIG. 8 and 9 and 10 | 601 KB | May 29, 2004 | Oct. 11, 2004 | Tif |
| Tiff 4.tif | | | | |
| Patent_Assignment | 158 KB | May 31, 2004 | Oct. 11, 2004 | Tif |
| 2.tif | | | | |
| Power_of_Attor- | 159 KB | May 31, 2004 | Oct. 11, 2004 | Tif |
| ney.tif | | | | |
| Small_Entity_{—} | 230 KB | May 30, 2004 | Oct. 11, 2004 | Tif |
| Statement.tif | | | | |
| Specification MH | 28 KB | May 31, 2004 | Oct. 11, 2004 | ASCII |

1. I claim the exclusive right to the use of vibratory fluidization of a particle bed in conjunction with a tooling plate, equipped with particle alignment holes, to place metallic and non-metallic particles.

2. In combination with claim 1, the embodiments of the invention in which an exclusive property or privilege is claimed are defined as follows: a machine for the placement of particulate matter consisting essentially of a particulate placement chamber, a tooling plate with particle alignment holes, a tooling plate frame that is attached to the particulate placement chamber, an input gate, and output gate, a clamp for clamping the work piece to the tooling plate, and multiple vibrators attached to either the particulate placement chamber, the tooling plate, the tooling plate frame, or any combination of the three.

3. In combination with claim 1, I claim the exclusive right to a method of filling a ball grid array with solder balls in a work cell including a tooling plate, a ball grid array, a riser cylinder and reservoir, said method comprising the steps of aligning said ball grid array with said tooling plate, said tooling plate having an array of holes for receiving solder balls, an input gate, said gate allowing the solder balls to flow from the reservoir onto the tooling plate's surface forming a solder ball bed that covers the tooling plate, a combination of vibrators, said vibrators having adjustable frequency and amplitude used to fluidize the layer of solder balls on the tooling plate, said tooling plate is vibrated to fluidize the layer of solder balls on its surface, during which gravity is operative to transfer the solder balls to array of holes for receiving solder balls, an output gate for removing excess loose solder balls, said output gate opening while the solder ball bed is fluidized, a riser cylinder to tilt the said tooling plate to allow the excess loose solder balls to flow from the said tooling plate thru said output gate and to be recaptured in said reservoir.
